(19) United States
(12) Patent Application Publication
(10) Pub. No.: US 2008/0264613 A1
(43) Pub. Date: Oct. 30, 2008

(54) STRUCTURE OF MEMORY HEAT SINK

(76) Inventor: Huang-Cheng CHU, Banqiao City (TW)

Correspondence Address: RABIN & BERDO, P.C., Suite 500, 1101 14 Street, N.W., Washington, DC, 20005, US

(21) Appl. No.: 11/739,829

(22) Filed: Apr. 25, 2007

(51) Int. Cl. H05K 7/20

(52) U.S. Cl. 165/104.33; 165/80.2; 361/700

(57) ABSTRACT

A memory heat sink is mainly used to provide the memory unit with increased heat dissipation and protection. The memory unit, which is sandwiched in between the bilateral heat spreaders gripped by clips, can be free from dust and have increased heat dissipation. The thermal conduction unit, which perches on the bilateral heat spreaders, can be adjusted to any desirable angle by slightly lifting up the clips. Such angle adjustment made in an easy and simple way would assure performance of a plurality of memory heat sinks, which is applicable to a plurality of memory units inserted in sockets on a main board. The angle adjustment would keep the memory heat sinks spaced to each other so as to increase the heat dissipation.

### BACKGROUND OF THE INVENTION

I. Field of the Invention

A memory heat sink is to fit a pair of bilateral heat spreaders onto surfaces of a memory unit so as to absorb and dissipate heat from the memory unit using thermal contact. In addition, said pair of bilateral heat spreaders that can grip the memory unit also provides perfect protection to the chips contained in the memory unit. Specifically, the present invention relates to a memory heat sink that uses a clip to grip a pair of bilateral heat spreaders so that part of them can form into a tube, in which the heat pipe of a thermal conduction unit is enclosed. Thus, the thermal conduction unit comprising a plurality of heat fins for increasing heat dissipation is tightly mounted on the bilateral heat spreaders, through which the heat generated by the memory body is conducted to the thermal conduction unit.

II. Description of the Prior Art

In common use, the memory unit installed in a PC is kept cool and from getting damaged with two heat spreaders, which grip or are stick directly to surface of the memory unit. The heat spreaders absorb and dissipate heat from the memory unit using direct thermal contact so as to assure performance of the memory unit.

The memory heat sink of the prior art mainly comprises a pair of bilateral heat spreaders and a thermal conduction unit, which is structured by a heat pipe with a plurality of heat fins on one end, increasing the memory heat sink's surface area contacting the air and thus increasing the heat dissipation rate. The memory unit and the thermal conduction unit are sandwiched in between the bilateral heat spreaders, which are put together by screws. Thus, the memory heat sink not only keeps the memory unit cool through thermal contact but also provides perfect protection to chips contained in the memory unit. With reference to FIG. 1, which is a three-dimensional exploded view of the prior art, the memory heat sink 10 comprises a pair of bilateral heat spreaders 101 and a thermal conduction unit 102. The memory unit 20 and the thermal conduction unit 102 are sandwiched in between the bilateral heat spreaders 101. Each of the bilateral heat spreaders 101 comprises a furrow cut into a shape that the thermal conduction unit 102 can fit in. The thermal conduction unit 102 is structured by an oblong-shaped heat pipe, which comprises a plurality of heat fins 1021 on one end. In addition, a plurality of bolts 1012 is excavated in surface of the bilateral heat spreaders 101 so that the bilateral heat spreaders 101 can be fastened together by screws. Put the memory unit and the thermal conduction unit between the bilateral heat spreaders. Fit the screws into bolts so as to fasten the bilateral heat spreaders one to the other, between which the memory unit 20 and the thermal conduction unit 102 are sandwiched in. Nevertheless, in the case where a plurality of memory units 20 is inserted in sockets on a main board, the heat fins 1021 on one thermal conduction unit 102 would jostle against those on the other unit, thus reducing the heat dissipation rate. In order to avoid such jostles between heat fins, the thermal conduction units 102 must be positioned in different angles so as to keep some space between one and another. But such angle adjustment is quite a task for the prior art due to its structure. It is required to loosen the screws 103 fitted in the bolts so as to separate the bilateral heat spreaders 101 for adjusting the thermal conduction unit to a suitable angle. Afterward fasten the bilateral heat spreaders together by screws. The memory unit and the thermal conduction unit are thus sandwiched in between the bilateral heat spreaders. It is clear that the memory heat sink of the prior art is beyond user-friendliness in terms of adjustment and installation.

### SUMMARY OF THE INVENTION

It is an object of the present invention to provide a memory heat sink, which avoids the foregoing drawbacks of the prior art. More specifically, main object of the present invention is to provide a memory heat sink, which comprises a thermal conduction unit with adjustable angle and can easily be installed. The present invention mainly uses a pair of bilateral heat spreaders to grip a memory unit and a thermal conduction unit, and the grip is further fastened by a plurality of clips. Structure of the present invention provides easiness not only in angle adjustment of the thermal conduction unit but also in assembly of the complete unit.

Desirable structure, assembly and features of the present invention will be better understood from the detailed description and drawings that follow, in which various embodiments of the disclosed invention are illustrated by way of example.

### BRIEF DESCRIPTION OF THE DRAWINGS

FIG. 1 is a three-dimensional exploded view of the prior art.

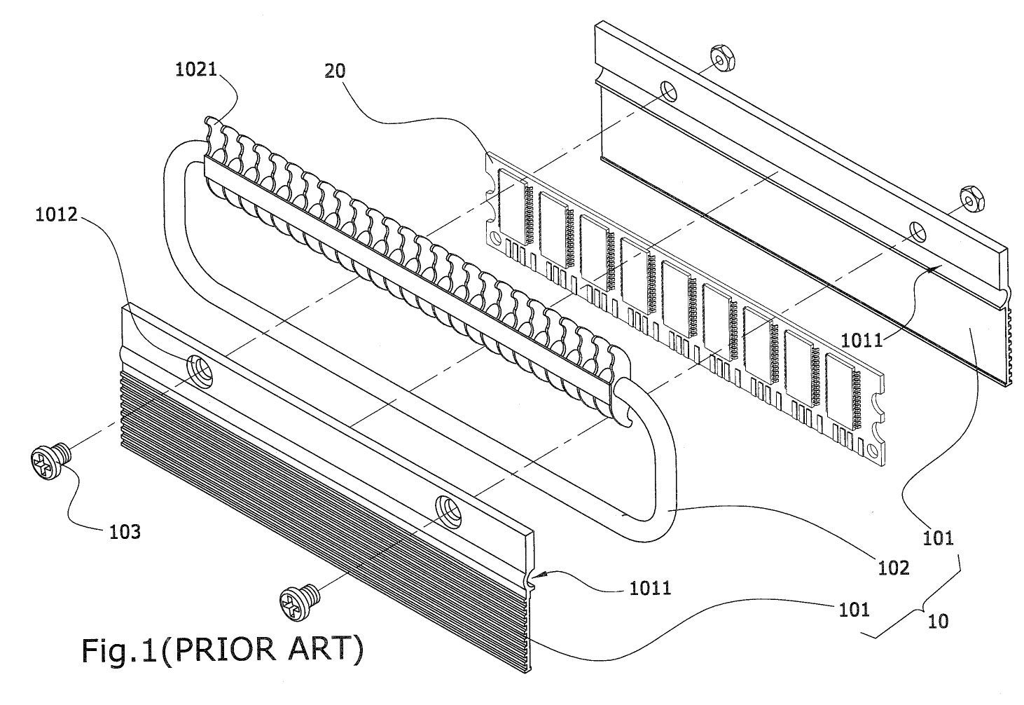

FIG. 2 is a three-dimensional exploded view of the invention.

FIG. 3 is a cross-sectional view of the invention.

FIG. 4 illustrates embodiment (I) of the invention.

FIG. 5 illustrates embodiment (II) of the invention.

FIG. 6 illustrates embodiment (III) of the invention.

FIG. 7 illustrates another embodiment of the invention.

### DESCRIPTION OF THE PREFERRED EMBODIMENTS

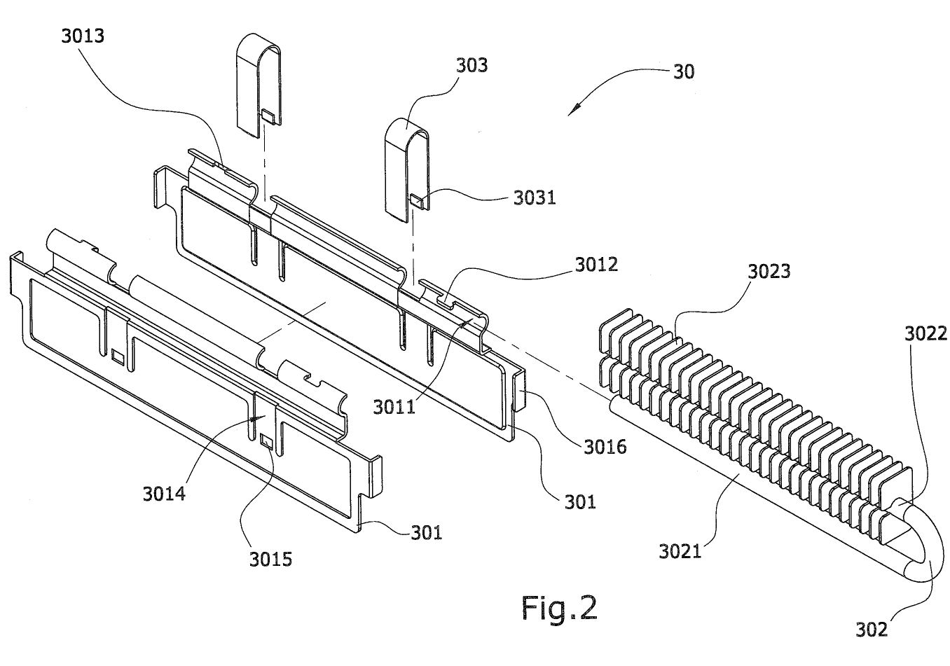

With reference to FIG. 2, which is a three-dimensional exploded view of the present invention, the memory heat sink 30 comprises a pair of bilateral heat spreaders 301, one thermal conduction unit 302 and a plurality of clips 303. Each of the bilateral spreaders 301 comprises a furrow 3011, which is formed on top edge and has a corresponding one formed on top edge of the other spreader, two bumps 3016, which are formed at two ends and have corresponding ones formed at two ends of the other spreader, a plurality of spacing portions 3014, which is a deep cut in the surface, and a plurality of mortises 3015, which is an excavation in the surface. The furrow 3011 on one of the bilateral heat spreaders comprises a tongue 3012 and a groove 3013, which have corresponding groove and tongue formed on furrow of the other heat spreader. Fit the tongues into the grooves so that the furrows 3011 on the bilateral heat spreaders can form into a tube. The thermal conduction unit 302 is a U-shaped heat pipe, one end of which is a heat pipe 3021 and the other end of which is a heat pipe with an array of fin-like protrusions 3022 to increase the memory heat sink's surface area contacting the air, and thus increasing the heat dissipation rate. The fin-like protrusions are called heat fins 3023. The clip 303 comprises a tenon 3031, which protrudes from surface of the inner side and can be wedged into the mortise 3015 excavated in surface of the bilateral heat spreader 301. Mount the thermal conduction unit 302 on the bilateral spreaders 301 to form into a complete memory heat sink 30 by following steps: lay the heat pipe 3021 between the two corresponding furrows 3011 on the bilateral heat spreaders; insert tongue 3012 on furrow of one heat spreader into groove 3013 on that of the other so as to combine the two furrows 3011 into a tube, in which the heat pipe 3012 is enclosed; lay the clips 303 astride said tube and fit in the spacing portions 3014 on the bilateral heat spreaders; wedge tenon 3031 on the clip 303 into its corresponding mortise 3015 on the heat spreader 301.

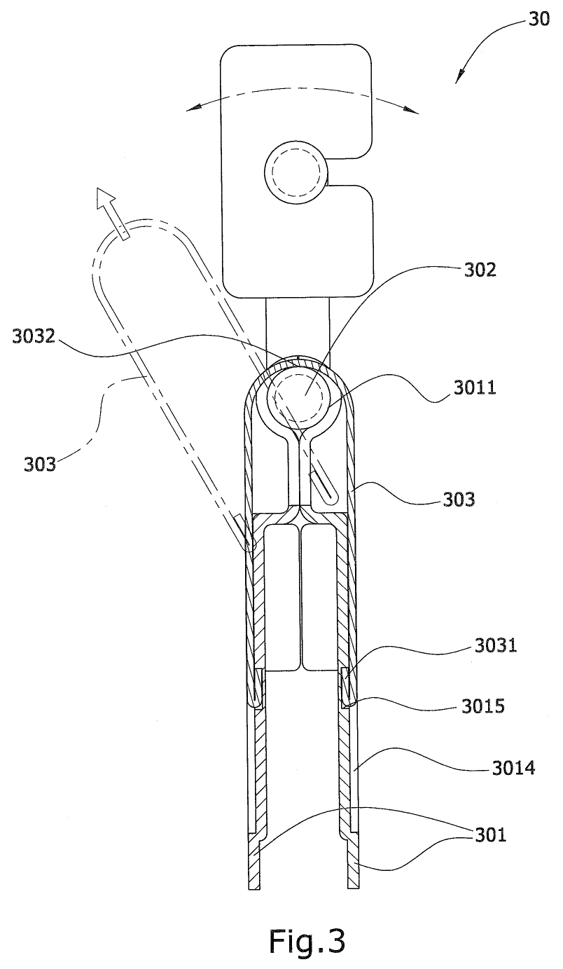

With reference to FIG. 3, which is a cross-sectional view of the present invention, the memory heat sink 30 comprises a pair of bilateral heat spreaders 301, a thermal conduction unit 302 and a plurality of clips 303. Mount the thermal conduction unit 302 on the bilateral heat spreaders 301 so as to form into a complete memory heat sink by following steps: lay the heat pipe 3021 between two corresponding furrows 3011 on the bilateral heat spreaders; fit the tongues and the grooves together so as to combine the two corresponding furrows into a tube, in which the heat pipe 3021 is enclosed; lay the clips 303 astride said tube and fit into the spacing portions 3014 cut in surface of the bilateral heat spreaders; wedge tenon 3031 on the clip 303 into its corresponding mortise 3015 on the spreader 301. The tenon 3031 protrudes from surface of inner side of the clip 303. The mortise 3015 is excavated in surface of the spreader 301. The U-shaped portion 3032 of the clip 303 grips said tube so as to further affix heat pipe of the thermal conduction unit 302. However, the thermal conduction unit 302 can perch on the bilateral heat spreaders in different angles, and angle adjustment can easily be made by slightly lifting up the clips 303, indicated by the arrow illustrated in FIG. 3.

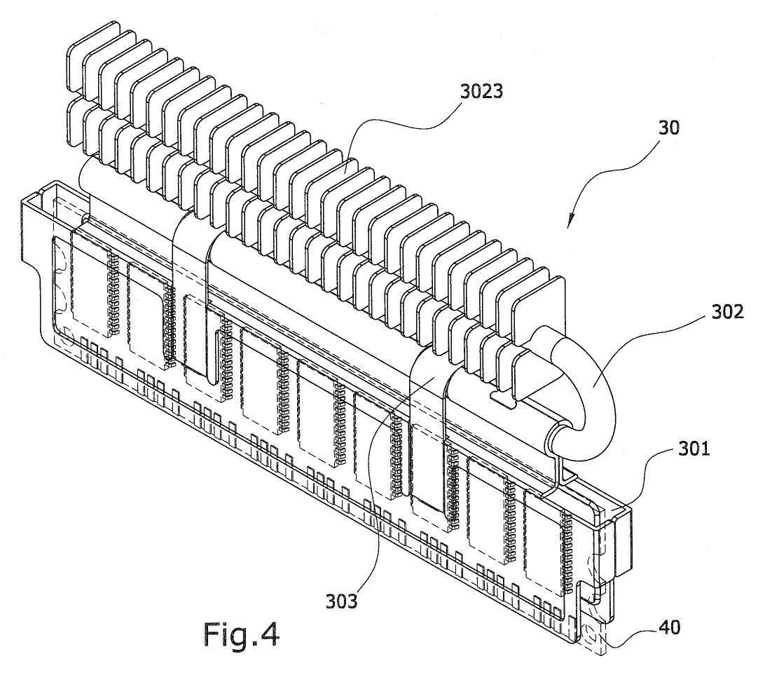

With reference to FIG. 4, which illustrates embodiment (I) of the present invention, the memory heat sink 30 comprises a pair of bilateral heat spreaders 301, a thermal conduction unit 302 and a plurality of clips 303. The memory unit 40 is sandwiched in between the bilateral heat spreaders 301 so that its surface is brought into contact with surfaces of the bilateral heat spreaders. The surface contact accelerates heat dissipating from surface of the memory unit 40 because the thermal conduction unit 302 is structured by a heat pipe with a plurality of heat fins 3023, which increase the memory heat sink's surface area contacting the air, and thus increasing the heat dissipation rate. The thermal conduction unit 302 can be adjusted to any desirable angle, and angle adjustment can be made by slightly lifting up the clips 303.

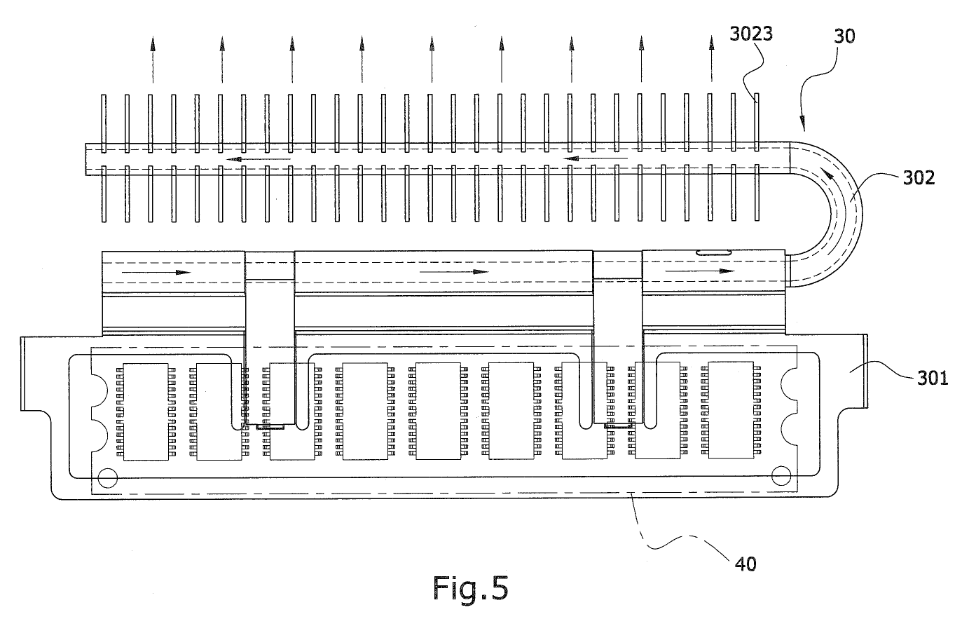

With reference to FIG. 5, which illustrates embodiment (II) of the present invention, the memory heat sink 30 uses the bilateral heat spreaders 301 to conduct the heat generated by the memory unit 40 to the thermal conduction unit 302 for increased heat dissipation, indicated by the arrow illustrated in the drawing. The thermal conduction unit 302 is a U-shaped heat pipe with a plurality of heat fins 3023, which increases the memory heat sink's surface area contacting the air, and thus increasing the heat dissipation rate. Heat generated by the memory unit 40 that is conducted by the bilateral spreaders to the thermal conduction unit can be rapidly dissipated into the air through the increased surface area—the plurality of heat fins 3023.

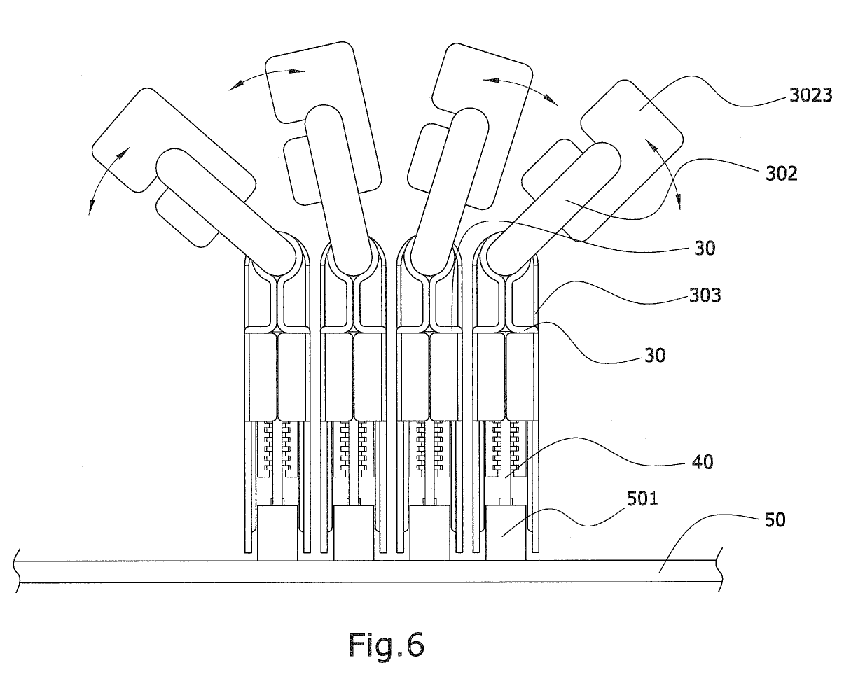

With reference to FIG. 6, which illustrates embodiment (III) of the present invention, a plurality of the memory unit 40 is inserted in the sockets 501 embedded on a main board 50 and each of which is sandwiched in between the bilateral heat spreaders, mounted with a thermal conduction unit. However, heat fins on one thermal conduction unit 302 would never jostle against those on the other because the thermal conduction unit can be adjusted to any desirable angle and the angle adjustment can easily be made by slightly lifting up the clips 303, indicated by the arrow in FIG. 5.

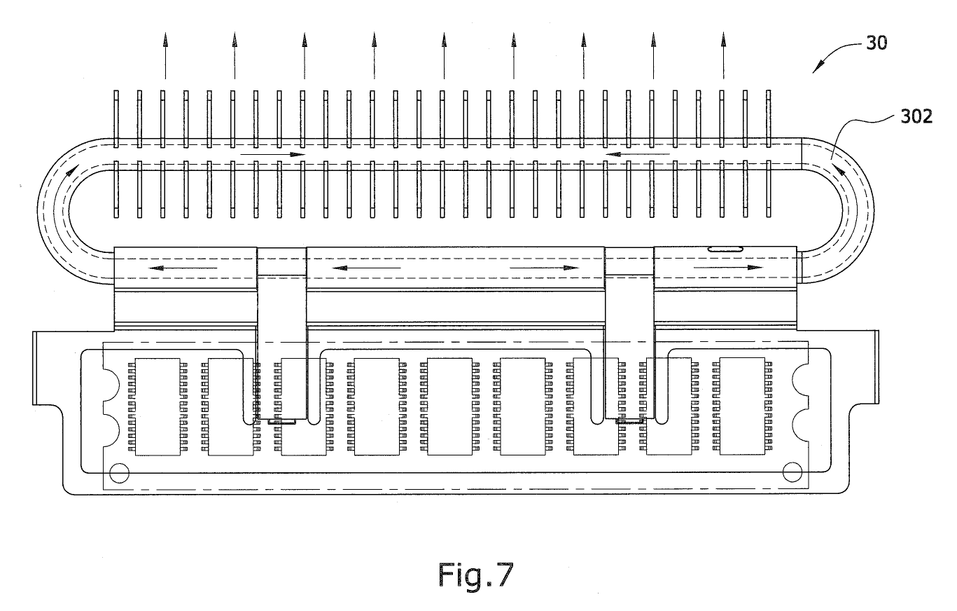

With reference to FIG. 7, which illustrates another embodiment of the present invention, the memory heat sink 30 comprises a thermal conduction unit 302, which is mainly structured by an ellipse-shaped heat pipe. The ellipse-shaped heat pipe can rapidly conduct the heat to the U-shaped portions at two ends (indicated by the arrow illustrated in FIG. 7), and thus increasing the heat dissipation rate of the memory heat sink 30.

It should be clear that structure of the present invention provides easiness not only in angle adjustment of the thermal conduction unit but also in assembly of the whole unit. Accordingly, the present invention possesses the practicability and the advancement of the industry.

While the present invention is susceptible to various modifications and alternative forms, the specific embodiments have been shown by way of example in the drawings and described in detail herein. However, it should be understood that the present invention is not intended to be limited to the particular form disclosed. Rather, the present invention is to cover all modifications, equivalents, and alternatives falling within the spirit and scope of the present invention as defined by the appended claims.

What is claimed is:

1. A memory heat sink, which grip a memory unit for surface contact, comprises:
a pair of bilateral heat spreaders, each of which consists of a furrow formed on top edge, a plurality of spacing portions cut in surface and a plurality of mortises excavated in surface; said furrows comprising tongues and grooves, fitting the tongues and the grooves so as to combine said two furrows into a tube;
a plurality of U-shaded clips, each of which comprises a tenon protruding from surface of one inner side and corresponding to the mortise on the bilateral heat spreader;
laying the clip astride said tube, fitting it into spacing portion and wedging its tenon into a corresponding mortise on the bilateral heat spreader so as to strengthen grip of the bilateral heat spreaders; and
a thermal conduction unit, which is structured by a U-shaped heat pipe with a plurality of heat fins at one end and can perch on said pair of bilateral heat spreaders.

2. The memory heat sink of claim 1, wherein a thermal film can be stick to opposite surfaces of the bilateral heat spreaders.

3. The memory heat sink of claim 1, wherein each of the bilateral heat spreaders consists of two bumps, formed respectively at two ends.

4. The memory heat sink of claim 1, wherein the thermal conduction unit is mainly structured by an ellipse-shaped heat pipe, which comprises U-shaped portions at two ends.

5. The memory heat sink of claim 1, wherein the thermal conduction unit is structured by an oblong-shaped heat pipe.
